(19) United States
(12) Patent Application Publication
(10) Pub. No.: US 2007/0215955 A1
(43) Pub. Date: Sep. 20, 2007

(54) Magnetic tunneling junction structure for magnetic random access memory

(76) Inventors: Te-Ho Wu, Yunlin (TW); Lin-Hsiu Ye, Yunlin (TW); Che-Hao Chang, Yunlin (TW); Tzu-Jung Chen, Yunlin (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/543,039

(22) Filed: Oct. 5, 2006

(30) Foreign Application Priority Data
Mar. 20, 2006 (TW) 95109488

(51) Int. Cl. H01L 29/76; H01L 29/94; H01L 31/00

(52) U.S. Cl. 257/401

(57) ABSTRACT

A magnetic tunneling junction structure for magnetic random access memory is disclosed. A composite structure includes at least a pinning layer, a barrier layer, a ferromagnetic layer and a free layer, and the material of the pinning layer and the free layer are perpendicularly anisotropic ferrimagnetic. As the structures include of several barrier layers, free layers and ferrimagnetic layers, that lower coercivity and high squareness for the hysteresis curves can be obtained, and reduction of the coercivity of the free layer can be achieved.

### RELATED APPLICATIONS

The present application is based on, and claims priorities from, Taiwan Application Serial Number 95109488, filed Mar. 20, 2006, the disclosure of which is hereby incorporated by reference herein in its entirety.

### BACKGROUND

1. Field of Invention

The present invention relates to a kind of magnetic tunneling junction structure for magnetic random access memory, and more particularly to a kind of magnetic tunneling junction structure for magnetic random access memory, which comprises multiple barrier layers and lowers the coercive field of free layers.

2. Description of Related Art

The magnetic random access memory (MRAM) is non-violate data storage memory, wherein the magnetic tunneling junction (MTJ) could be the magnetoresistance device for data storage.

The conventional structure of a magnetic tunneling junction is a usually a sandwich structure like “ferromagnetic layer/barrier layer/ferromagnetic layer” discovered in 1995. The sandwich structure induces the “tunnel magnetoresistance (TMR)” effect, and the magnetoresistance of TMR at room temperature is greater than the “giant magnetoresistance (GMR)” discovered in 1988. In the last decade, many research institutes made an effort to increase the magnetoresistance at room temperature. It is hoped that practical applications of MRAM will be developed soon.

There are two conventional methods to raise the value of tunneling magnetoresistance: first, the barrier layer material can be changed into materials like aluminum oxide or magnesium oxide; second, ferromagnetic materials with high spin polarization, such as CoFeB.

Reference is made to FIG. 1, which illustrates the conventional structure of a magnetic tunneling junction for magnetic random access memory. The structure of a magnetic tunneling junction 100 includes a substrate 110, a lower electrode 120, a free layer 130, a ferrimagnetic module 140, a barrier layer 160 and an upper electrode 170.

The ferrimagnetic module 140 includes a lower ferrimagnetic layer 141, an upper ferrimagnetic layer 142 and a barrier layer 150. The barrier layer 150 is between the lower ferrimagnetic layer 141 and the upper ferrimagnetic layer 142 to perform tunneling magnetoresistance effect.

Reference is made to FIG. 2, which illustrates a hysteresis curve of the structure of a magnetic tunneling junction 100 between −10,000 and 10,000 Oersted (Oe). The squareness of the structure of the magnetic tunneling junction 100 is not satisfied. Squareness is a ratio of remanent magnetization (Mᵣ) and saturation magnetization (Mₛ). When the ratio is closer to 1, the squareness is much better. Referring to FIG. 2, the squareness of the hysteresis curve is 0.567, and the coercive field of the hysteresis curve is 822.8 Oersted.

Reference is made to FIG. 3, which illustrates a hysteresis curve of the magnetic tunneling junction 100 when a magnetic field between −1,000 and 1,000 Oersted (Oe) is applied. The squareness of the hysteresis curve is 0.6026, and the coercive field of the hysteresis curve is 100 Oersted.

The disadvantages of the aforementioned structures and methods are:

1. The coercive field intensity from the free layer in the conventional structure of a magnetic tunneling junction is high, therefore, it requires a more powerful applied magnetic field to drive the magnetic tunneling junction. Hence the power consumption is required higher and the adjacent layers in the structure of the magnetic tunneling junction are affected.

2. The squareness of the hysteresis curve of the conventional structure for the magnetic tunneling junction is not satisfied. The squareness is an important parameter for memory or switch devices. Squareness could affect the characteristics, for example, the speed for data reads and writes or the response time it takes for the switch to be switched on and switched off.

The above-mentioned problems happened frequently in the conventional method and the magnetic devices consist of the multi-layer films of various materials. Therefore, the current invention provides the solution for the above-mentioned problems through a magnetic tunneling junction which requires a smaller applied magnetic field and generates a hysteresis curve with a higher squareness.

### SUMMARY

In order to solve the above-mentioned and other problems and to achieve the technical advantages of the present invention, the present invention provides a method of measuring anisotropic energy. The method can measure the anisotropic energy from the magnetic structure consisting of multiple materials.

Therefore, an objective of the present invention is to provide a magnetic tunneling junction structure for a magnetic memory component. The structure could reduce the coercive field of the free layer, and improve the squareness of the hysteresis curve.

According to the aforementioned objectives of the present invention, a magnetic tunneling junction structure for MRAM is described. The magnetic structure includes multiple barrier layers, ferrimagnetic layers, pinned layers and free layers. The multiple ferrimagnetic layers include horizontal or perpendicular polarized ferrimagnetic layers. Both the pinned layers and free layers contain perpendicular anisotropic magnetizations. The multiple barrier layers of the magnetic structure is disposed between the horizontal polarized ferrimagnetic layers, and it also could be disposed between two free layers. The material of the barrier layer is a nonmagnetic and nonconducting film.

### BRIEF DESCRIPTION OF THE DRAWINGS

The accompanying drawings are included to provide a further understanding of the invention and are incorporated in and constitute a part of this specification. The drawings illustrate embodiments of the invention and, together with the description, serve to explain the principles of the invention. In the drawings,

FIG. 1 illustrates an isometric view of the conventional magnetic tunneling junction structure;

FIG. 2 is a hysteresis curve plot of a magnetic tunneling junction with a conventional structure when a magnetic field between −10,000 and 10,000 Oersted is applied;

FIG. 3 is a hysteresis curve plot of a magnetic tunneling junction with a conventional structure when a magnetic field between −1,000 and 1,000 Oersted is applied;

FIG. 4 illustrates an isometric view of a magnetic tunneling junction structure for a preferred embodiment of the present invention;

FIG. 5 illustrates a hysteresis curve plot of a magnetic tunneling junction with the structure of the present preferred embodiment when a magnetic field between −10,000 and 10,000 Oersted is applied;

FIG. 6 illustrates a hysteresis curve plot of a magnetic tunneling junction with the structure of the present preferred embodiment when a magnetic field between −1,000 and 1,000 Oersted is applied;

FIG. 7 illustrates an isometric view of the magnetic tunneling junction structure for the preferred embodiment of the present invention;

FIG. 8 illustrates a hysteresis curve plot of a magnetic tunneling junction with the structure of the present preferred embodiment when a magnetic field between −10,000 and 10,000 Oersted is applied; and

FIG. 9 illustrates a hysteresis curve plot of a magnetic tunneling junction with the structure of the present preferred embodiment when a magnetic field between −1,000 and 1,000 Oersted.

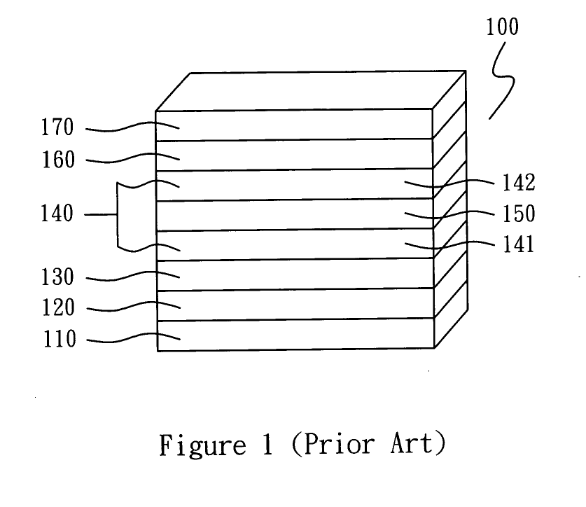

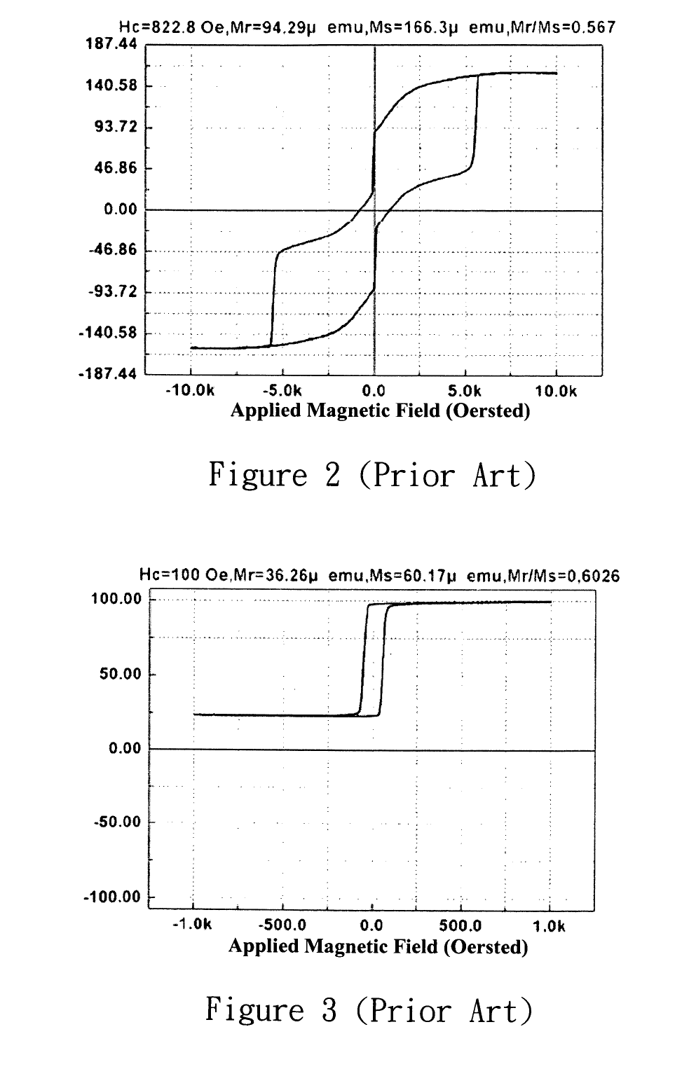

### DESCRIPTION OF THE PREFERRED EMBODIMENTS

Reference is now made in detail to the present preferred embodiments of the invention, examples are illustrated in the accompanying drawings. Wherever possible, the same reference numbers are used in the drawings and the description to refer to the same or like parts.

While the specification concludes with claims defining the features of the invention that are regarded as novel, it is believed that the invention is better understood from a consideration of the following description in conjunction with the figures, in which like reference numerals are carried forward.

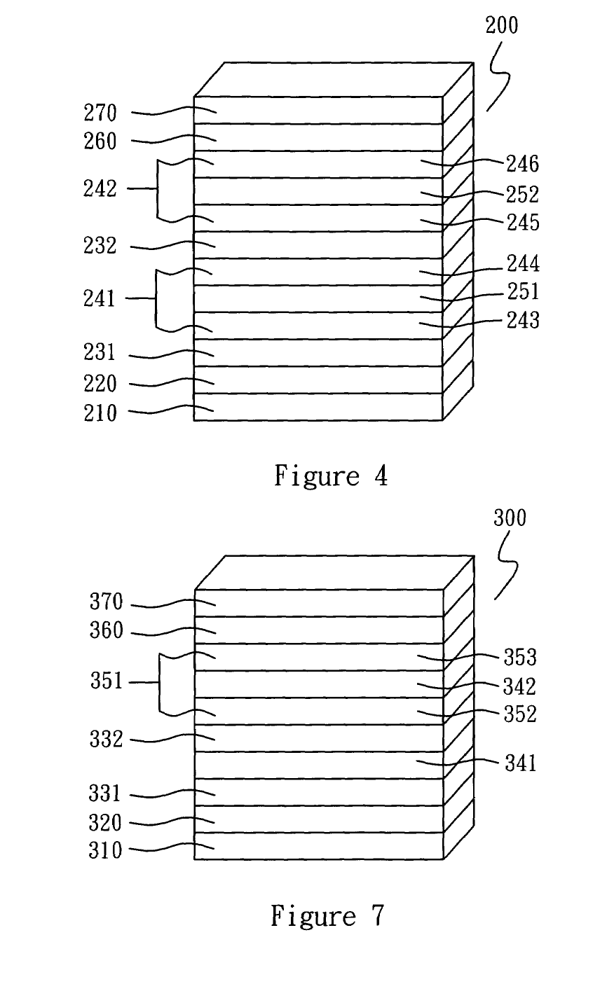

Reference is made to FIG. 4, which illustrates the magnetic tunneling junction structure of the preferred embodiment of the present invention. A magnetic tunneling junction structure 200 includes a substrate 210, a lower electrode 220, a first free layer 231, a second free layer 232, a lower ferrimagnetic module 241, an upper ferrimagnetic module 242, a first barrier layer 251, a second barrier layer 252, a pinned layer 260 and an upper electrode 270.

The material of the substrate 210 is an insulator, in this case is silicon (Si). The material of the lower electrode 220 and the upper electrode 270 is metal, in this case is platinum (Pt). The material of the first free layer 231 and the second free layer 232 are selected from ferromagnetic groups with small coercivity, in this case is GdFeCo. The materials of the lower ferrimagnetic module 241 and the upper ferrimagnetic module 242 are horizontally or perpendicularly polarized films. The materials of the first barrier layer 251 and the second barrier layer 252 are aluminum oxide, magnesium oxide or silicon nitride, which are nonmagnetic and nonconducting films. The material of the pinned layer 260 is selected from ferromagnetic groups with large coercivity, in this case is TbFeCo.

The lower ferrimagnetic module 241 includes a first ferrimagnetic layer 243 and a second ferrimagnetic layer 244. The first barrier layer 251 is between the first ferrimagnetic layer 243 and the second ferrimagnetic layer 244, which produces the tunneling magnetoresistance effect. The upper ferrimagnetic module 242 includes a third ferrimagnetic layer 245 and a fourth ferrimagnetic layer 246. The second barrier layer 252 is disposed between the third ferrimagnetic layer 245 and the fourth ferrimagnetic layer 246, which also perform tunneling magnetoresistance effect.

The aforementioned materials use several targets and are deposited by sputter in order to form the structure of the magnetic tunneling junction.

The lower electrode 220 is disposed on the substrate 210 and the lower electrode 220 through sputtering deposition, and the thickness of the lower electrode 220 is 25 nanometers (nm). The first free layer 231 is disposed on the lower electrode 220 and the first free layer 231, and the thickness of the first free layer 231 is 50 nanometers (nm). The first ferrimagnetic layer 243 is disposed on the first free layer 231 and the thickness of the first ferromagnetic layer 243 is 2 nanometers (nm). The first barrier layer 251 is disposed on the first ferromagnetic layer 243 and the thickness of the first barrier layer 251 is 1 nanometer (nm). The second ferrimagnetic layer 244 is disposed on the first barrier layer 251 and the thickness of the second ferromagnetic layer 244 is 2 nanometers (nm). The second free layer 232 is disposed on the second ferromagnetic layer 244 and the thickness of the second free layer 232 is 50 nanometers (nm). The third ferrimagnetic layer 245 is disposed on the second free layer 232 and the thickness of the third ferromagnetic layer 245 is 2 nanometers (nm). The second barrier layer 252 is disposed on the third ferromagnetic layer 245 and the thickness of the second barrier layer 252 is 1 nanometer (nm). The fourth ferromagnetic layer 246 is disposed on the second barrier layer 252 and the thickness of the fourth ferromagnetic layer 246 is 2 nanometers (nm). The pinned layer 260 is disposed on the fourth ferromagnetic layer 246 and the thickness of the pinned layer is 35 nanometers (nm). Finally, the upper electrode 270 is disposed on the pinned layer 260 and the thickness of the upper electrode is 25 nanometer (nm).

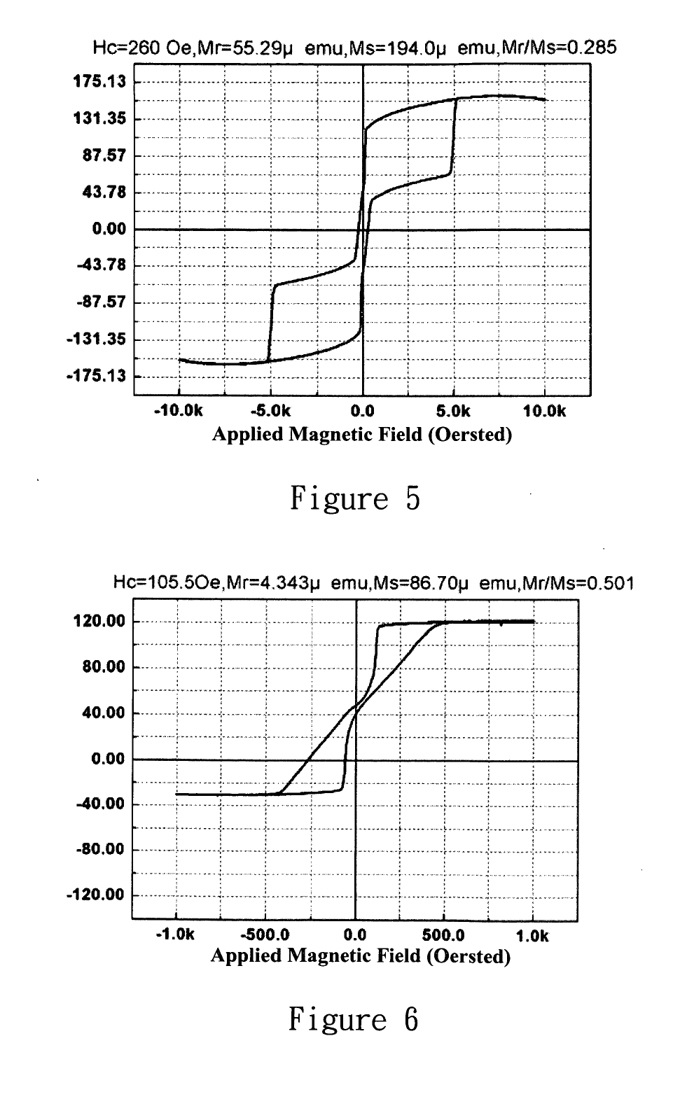

Reference is made to FIG. 5, which illustrates a hysteresis curve plot of the structure of the magnetic tunneling junction structure 200 when a magnetic field between −10,000 and 10,000 Oersted is applied. Although the squareness of hysteresis curve of the magnetic tunneling junction structure 200 is 0.285, the intensity of the coercive field is very much lower down than coercive field for the magnetic tunneling junction with a conventional structure, the intensity of the coercive field for the current invention is, for example, 260 Oersted. Reference is made to FIG. 6, which illustrates a hysteresis curve plot of a magnetic tunneling junction structure 200 when a magnetic field between −1,000 to 1,000 Oersted is applied. In this case, the intensity of the coercive field is 105.5 Oersted. The squareness of the hysteresis curve is 0.501.

Reference is made to FIG. 7, which illustrates the structure of a magnetic tunneling junction 300 of the preferred embodiment of the present invention. The structure of the magnetic tunneling junction 300 includes at least a substrate 310, a lower electrode 320, a first free layer 331, a second free layer 332, a first barrier layer 341, a second barrier layer 342, a ferrimagnetic module 351, a pinned layer 360 and an upper electrode 370.

The material of the substrate 310 is Si or SiN, in this case is Si. The material of the lower electrode 320 and the upper electrode 370 are Pt, Ru, Ta or Ti, in this case is Pt. The material of the first layer 331 and the second free layer 332 are GdFeCo, TbFeCo, DyFeCo or Co/Pt multilayer, in this case is GdFeCo. The materials of the first barrier layer 341 and the second barrier layer 342 are aluminum oxide, magnesium oxide or silicon nitride, which are nonmagnetic and nonconducting films. The material of the ferrimagnetic module 351 is FeCo or FeCoB, in this case is FeCo. The material of the pinned layer 360 is GdFeCo, TbFeCo, DyFeCo or Co/Pt multilayer, in this case is TbFeCo.

The structure of magnetic tunneling junction is constructed through depositing to from the aforementioned materials using physical vapor deposition (PVD).

The lower electrode 320 is deposited on the substrate 310 and the lower electrode 320 has a thickness of 25 nanometers (nm). The first free layer 331 is then disposed on the lower electrode 320 and the thickness of the first free layer 331 is 50 nanometers (nm). The first barrier layer 341 is disposed on the first free layer 331. The second free layer 332 is disposed on the first barrier layer 341 and the second free layer 332, and the thickness is 50 nanometers (nm). The first ferrimagnetic layer 352 is disposed on the second free layer 332 and the thickness of the first ferromagnetic layer 352 is 2 nanometers (nm). The second barrier layer 342 is disposed on the first ferrimagnetic layer 352. The second ferrimagnetic layer 353 is disposed on the second barrier layer 342 and the the thickness of second ferromagnetic layer 353 is 2 nanometers (nm). The pinned layer 360 is disposed on the second barrier layer 342 and the thickness of the pinned layer 360 is 35 nanometers (nm). Finally, the upper electrode 370 is disposed on the pinned layer 360 and the thickness of the upper electrode 370 is 25 nanometers (nm).

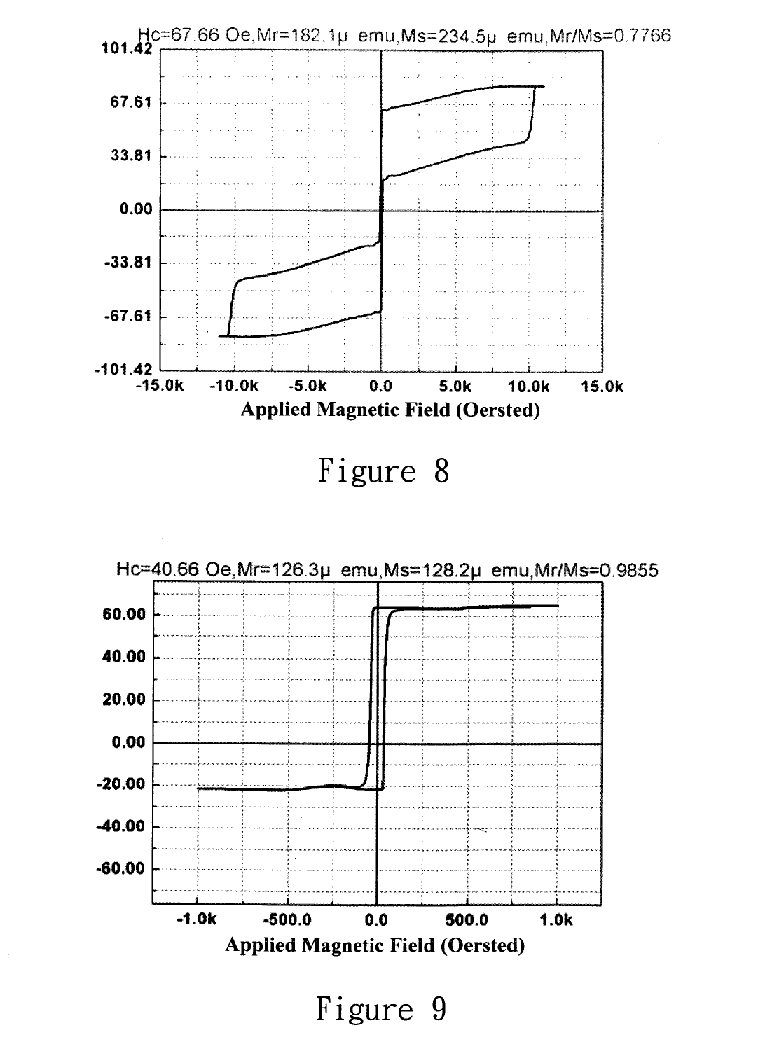

Reference is made to FIG. 8, which illustrates a hysteresis curve plot of the magnetic tunneling junction 300 when a magnetic field between −10,000 and 10,000 Oersted is applied. The intensity of the coercive field is 67.66 Oersted. The squareness of the hysteresis curve is 0.7766. Reference is made to FIG. 8, which illustrates a hysteresis curve plot of the magnetic tunneling junction 300 when a magnetic field between −1,000 and 1,000 Oersted is applied. The intensity of the coercive field is much lower than the conventional structure, normally is larger than 200, in the case of the present invention is 40.66 Oersted. The squareness of the hysteresis curve in the case of the present invention is 0.9855, while the conventional structure can only present the data normally smaller than 0.7.

The difference between the structure of the magnetic tunneling junction 200 and the structure of the magnetic tunneling junction 300 is that in the 10 structure of the magnetic tunneling junction 300 there are no horizontal polarized ferrimagnetic layers disposed above or beneath the multiple barrier layers of the in the structure of the magnetic tunneling junction 300.

According to the composition and the embodiments above, there are many advantages of the present invention over the prior art, such as:

1. The coercive field of the structure of magnetic tunneling junction with multiple barrier layers is much lower than the coercive field of conventional structures. Hence, the intensity of the applied magnetic field can be reduced, and the power consumption of the magnetic device can be lowered.

2. The squareness of the hysteresis curve of the structure of the magnetic tunneling junction with multiple barrier layers is much better than the squareness of the hysteresis curve for a magnetic tunneling junction with a conventional structure. Hence, the structure described above is more suitable for a memory device or a switch component.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A structure of a magnetic tunneling junction for magnetic random access memory, comprising:
multiple barrier layers, the multiple barrier layers are nonmagnetic and nonconducting films;
at least one ferrimagnetic module, the ferrimagnetic module composed of at least two polarized films;
a free layer, the free layer is a perpendicular anisotropic ferrimagnetic film, and multiple magnetizations of the free layer are free to rotate with an applied magnetic field; and
a pinned layer, the pinned layer is a perpendicular anisotropic ferrimagnetic film.

2. The magnetic tunneling junction structure for magnetic random access memory of claim 1, wherein two polarized films are horizontally polarized films.

3. The magnetic tunneling junction structure for the magnetic random access memory of claim 1, wherein two polarized films are perpendicular polarized films.

4. The magnetic tunneling junction structure for the magnetic random access memory of claim 1, wherein a magnetoresistance of the multiple barrier layers is varied significantly at room temperature.

5. The magnetic tunneling junction structure for magnetic random access memory of claim 1, wherein the multiple barrier layers are between two polarized films of the ferrimagnetic module.

6. The magnetic tunneling junction structure for the magnetic random access memory of claim 1, wherein the material for the multiple barrier layers is non-magnetic films or non-conductive films.

7. The magnetic tunneling junction structure for magnetic random access memory of claim 1, wherein the multiple barrier layers is aluminum oxide, magnesium oxide, or silicon nitride.

8. The magnetic tunneling junction structure for magnetic random access memory of claim 1, wherein thickness of the barrier is ranged from 0.5 nm to 3.5 nm.

9. The magnetic tunneling junction structure for magnetic random access memory of claim 1, wherein the thickness of the ferrimagnetic module is ranged from 1 nm to 4 nm.

10. The magnetic tunneling junction structure for magnetic random access memory of claim 1, wherein material of the free layer is GdFeCo, TbFeCo, DyFeCo or Co/Pt multilayer.

11. The magnetic tunneling junction structure for magnetic random access memory of claim 1, wherein thickness of the free layer is ranged from 35 nm to 60 nm.

12. The magnetic tunneling junction structure for magnetic random access memory of claim 1, wherein material of the pinned layer is GdFeCo, TbFeCo, DyFeCo or Co/Pt multilayer.

13. The magnetic tunneling junction structure for magnetic random access memory of claim 1, wherein thickness of the pinned layer is ranged from 30 nm to 40 nm.

14. The magnetic tunneling junction structure for magnetic random access memory of claim 1, wherein the magnetic tunneling junction structure has multiple electrodes.

15. The magnetic tunneling junction structure for magnetic random access memory of claim 14, wherein material of the electrodes is Pt, Ru, Ta or Ti.

16. The magnetic tunneling junction structure for magnetic random access memory of claim 14, wherein thickness of the electrodes is ranged from 5 nm to 25 nm.
